(19) United States
(12) Patent Application Publication
(10) Pub. No.: US 2010/0148240 A1
(43) Pub. Date: Jun. 17, 2010

(54) SEMICONDUCTOR DEVICE AND MANUFACTURING METHOD THEREOF

(76) Inventor: JAE YUHN MOON, Chungbuk (KR)

Correspondence Address: SALIWANCHIK LLOYD & SALIWANCHIK;A PROFESSIONAL ASSOCIATION, PO Box 142950, GAINESVILLE, FL, 32614, US

(21) Appl. No.: 12/621,151

(22) Filed: Nov. 18, 2009

(30) Foreign Application Priority Data
Dec. 15, 2008 (KR) 10-2008-0127518

(51) Int. Cl. H01L 29/792; H01L 21/28

(52) U.S. Cl. 257/324; 438/591; 257/E29.309; 257/E21.21

(57) ABSTRACT

Disclosed are a semiconductor device and a manufacturing method thereof. The semiconductor device includes a first insulating layer pattern on a semiconductor substrate, a second insulating layer including fluorine on the first insulating layer pattern, a third insulating layer pattern on the second insulating layer pattern, and a polysilicon pattern on the third insulating layer pattern. The fluorine is included in the second insulating layer that may be a nitride layer that stores data in a flash memory device, so that data retention and reliability are improved without exerting an influence upon capacitor characteristics.

### CROSS-REFERENCE TO RELATED APPLICATION

This application claims the benefit under 35 U.S.C. §119 of Korean Patent Application No. 10-2008-0127518, filed Dec. 15, 2008, which is hereby incorporated by reference in its entirety.

### BACKGROUND

A flash memory device is a non-volatile memory device that can retain information stored in a memory cell even if power is not supplied to the flash memory device and can electrically erase the information at a high speed while being mounted on a printed circuit board.

A non-volatile memory, which can be electrically erasable and programmable, is called an EEPROM (Electrically Erasable Programmable Read Only Memory). A non-volatile memory device employing a floating gate cell has been extensively used for a long time.

Recently, as semiconductor devices have been highly integrated, scale-down of the conventional floating gate cell is required. However, there is limitation in scale-down of the conventional floating gate cell since high voltage is necessary during programming/erasing operations and process margin must be ensured to define tunnels, etc. For this reason, various studies have been pursued to replace the floating gate cell with silicon-oxide-nitride-silicon (SONOS), ferroelectric random access memory (FeRAM), Single Electron Transistor (SET), nitrided read only memory (NROM), etc. Among them, the SONOS cell has been spotlighted as a next-generation cell that substitutes for the floating gate cell.

### BRIEF SUMMARY

Embodiments provide a semiconductor device capable of being used in a flash memory device and a manufacturing method thereof. In an embodiment, a semiconductor device having a SONOS structure and a manufacturing method thereof is provided, capable of reducing trap density by adding fluorine to a nitride layer that stores data, thereby improving data retention characteristics in the semiconductor device.

A semiconductor device according to an embodiment includes a first insulating layer pattern on a semiconductor substrate, a second insulating layer including fluorine on the first insulating layer pattern, a third insulating layer pattern on the second insulating layer pattern, and a polysilicon pattern on the third insulating layer pattern.

A method of manufacturing a semiconductor device according to an embodiment includes forming a first insulating layer on a semiconductor substrate, forming a second insulating layer on the first insulating layer by using gas containing fluorine, forming a third insulating layer on the second insulating layer, forming a polysilicon layer on the third insulating layer, and forming a gate pattern by patterning the polysilicon layer, the third insulating layer, the second insulating layer, and the first insulating layer.

A method of manufacturing a semiconductor device according to an embodiment includes forming a first insulating layer on a semiconductor substrate, forming a second insulating layer on the first insulating layer, implanting fluorine into the second insulating layer through an ion implantation process, forming a third insulating layer on the second insulating layer, forming a polysilicon layer on the third insulating layer, and forming a gate pattern by patterning the polysilicon layer, the third insulating layer, the second insulating layer, and the first insulating layer.

A method of manufacturing a semiconductor device according to an embodiment includes forming a first insulating layer on a semiconductor substrate, forming a second insulating layer on the first insulating layer, implanting fluorine into the second insulating layer through a plasma process, forming a third insulating layer on the second insulating layer, forming a polysilicon layer on the third insulating layer, and forming a gate pattern by patterning the polysilicon layer, the third insulating layer, the second insulating layer, and the first insulating layer.

### BRIEF DESCRIPTION OF THE DRAWINGS

FIGS. 1 to 6 are cross-sectional views showing a manufacturing procedure for a semiconductor device according to an embodiment.

### DETAILED DESCRIPTION

Hereinafter, a semiconductor device and a manufacturing method thereof according to embodiments will be described with reference accompanying drawings. In the description of the embodiment of the disclosure, it will be understood that, when a layer (or film), a region, a pattern, or a structure is referred to as being “on (above/over/upper)” or “under (below/down/lower)” another substrate, another layer (or film), another region, another pad, or another pattern, it can be directly on the other substrate, layer (or film), region, pad, or pattern, or intervening layers may also be present. Furthermore, it will be understood that, when a layer (or film), a region, a pattern, a pad, or a structure is referred to as being “between” two layers (or films), regions, pads, or patterns, it can be the only layer between the two layers (or films), regions, pads, or patterns, or one or more intervening layers may also be present. Thus, it should be determined by the technical spirit of the present disclosure.

In the following description of the disclosure, a detailed description of known functions and configurations incorporated herein will be omitted when it may make the subject matter of the present invention rather unclear.

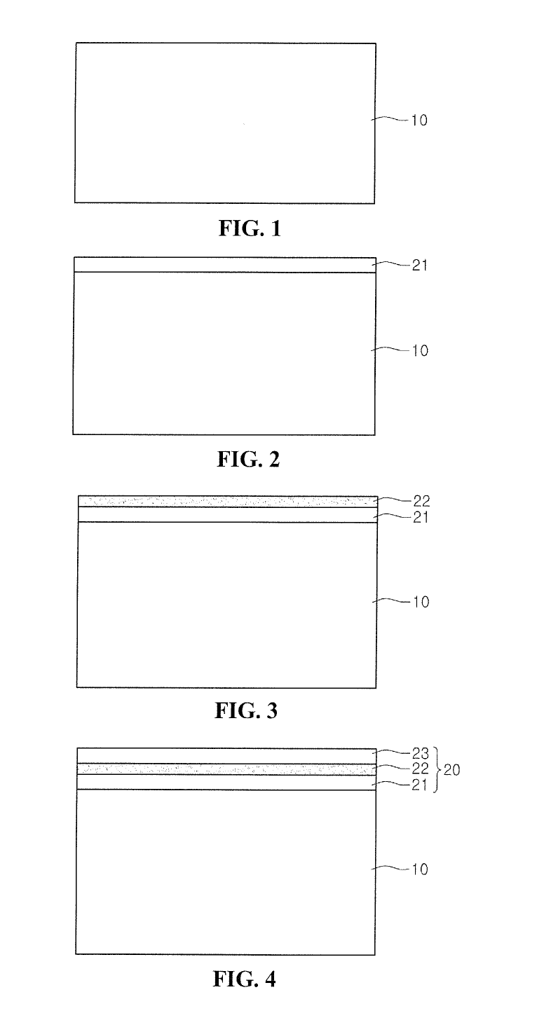

FIGS. 1 to 6 are cross-sectional views showing the manufacturing procedure for a semiconductor device according to an embodiment.

As shown in FIG. 1, a semiconductor substrate 10 is prepared.

The semiconductor substrate 10 may include a silicon substrate.

An isolation layer (not shown) can be formed on the semiconductor substrate 10 to define an active area. For instance, a trench is formed in the semiconductor substrate 10 and an oxide layer is filled in the trench, thereby forming the isolation layer (not shown).

As shown in FIG. 2, a first insulating layer 21 is formed on the semiconductor substrate 10.

The first insulating layer 21 can be deposited through a plasma enhanced chemical vapor deposition (PECVD) process.

The first insulating layer 21 may include an oxide layer.

The first insulating layer 21 may have a thickness of about 5 to 100 Å.

When the programming or erasing operation is performed in the non-volatile memory device, the first insulating layer 21 may serve as a tunnel oxide layer.

Then, as shown in FIG. 3, a second insulating layer 22 is formed on the first insulating layer 21.

The second insulating layer 22 may include a silicon nitride layer.

In the non-volatile memory semiconductor memory device, the second insulating layer 22 traps charges to execute the program.

After the second insulating layer 22 has been formed, fluorine can be implanted into the second insulating layer 22. That is, in a specific embodiment, the fluorine is implanted into the silicon nitride layer.

The fluorine is bonded with silicon in the silicon nitride layer, so that the number of dangling bonds is reduced, thereby reducing trap density.

Thus, data noise, which is caused due to repulsive effect between electrons when too many electrons are trapped in the second insulating layer 22, can be reduced.

That is, since the fluorine is implanted into the second insulating layer 22, the charge trap capability of the second insulating layer 22 can be adjusted, so that data retention characteristics and reliability of data can be improved.

In addition, if the trap density is reduced in the second insulating layer 22, charge coulomb repulsion may be reduced when data program is executed, so that capacitor characteristics of the nitride layer can be maintained. Accordingly, the manufacturing cost can be reduced without changing design of other parts.

In addition, the fluorine implanted into the second insulting layer 22 can be stably bonded with a silicon dangling bond of Si₃N₄.

The second insulating layer 22 may have a thickness of about 5 to 100 Å.

Hereinafter, a process for implanting the fluorine into the second insulating layer 22 will be described.

The fluorine can be implanted into the second insulating layer 22 through a plasma scheme or an implantation scheme.

In the case of the plasma scheme, after depositing the second insulating layer 22, the fluorine is plasma-processed by supplying C₄F₈ gas at the flow rate of 10˜20 sccm under the power of 1000˜1500 W such that the fluorine is implanted into the second insulating layer 22.

In the case of the implantation process, after depositing the second insulating layer 22, the fluorine is implanted into the second insulating layer 22 by supplying F+ ions at a dose of 1×10¹¹˜5×10¹³ cm⁻² by using an implant injector.

In yet another embodiment, a nitride layer containing the fluorine can be formed by supplying SiF₄ and NH₃ gas when the second insulating layer 22 is deposited.

In this case, the SiF₄ gas is supplied at the flow rate of 1˜1500 sccm under the pressure of 1 to 100 mTorr, and the ratio of the SiF₄ gas to the NH₃ gas is (1˜3):(4˜10).

Then, as shown in FIG. 4, a third insulating layer 23 is formed on the second insulating layer 22.

The third insulating layer 23 may include a silicon oxide layer.

The third insulating layer 23 may have a thickness of about 5 to 100 Å.

The first to third insulating layers 21 to 23 constitute an ONO layer 20 as the dielectric layers.

The first insulating layer 21 can provide a tunneling oxide layer, and the charges pass through the first insulating layer 21 from the crystalline silicon layer of the substrate 10.

The second insulating layer 22 can provide a nitride layer capable of trapping the charges.

The third insulating layer 23 can provide a blocking oxide layer for insulating the nitride layer from the gate electrode.

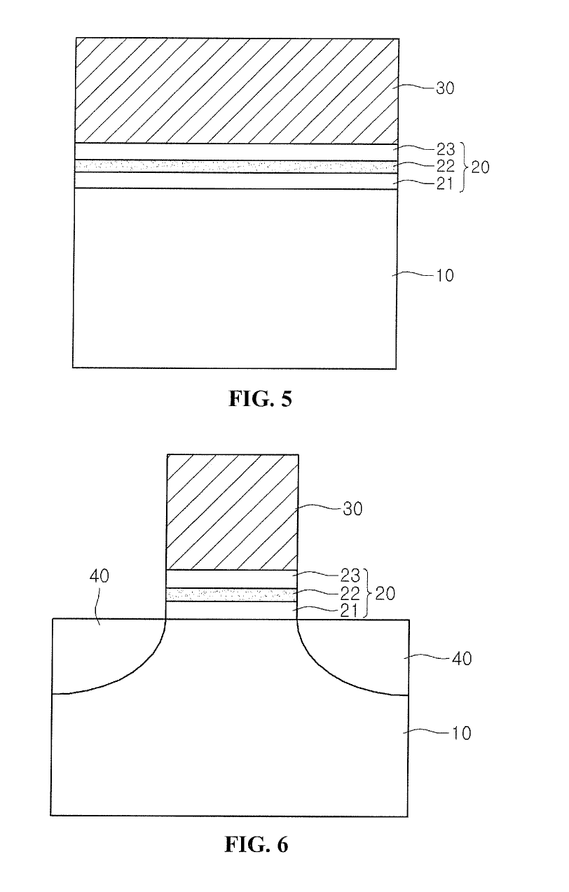

Then, as shown in FIG. 5, a polysilicon layer 30 is formed on the third insulating layer 23.

The polysilicon layer 30 may have a thickness of about 1000 to 3000 Å.

After that, as shown in FIG. 6, a gate pattern of the non-volatile memory device is formed by patterning the polysilicon layer 30, the third insulating layer 23, the second insulating layer 22, and the first insulating layer 21.

Then, a source and drain area 40 is formed by implanting high-concentration impurities onto the semiconductor substrate 10 at both sides of the gate pattern.

The SONOS device manufactured through the above process can reduce the trap density by bonding the silicon dangling bond with the fluorine through the implantation of the fluorine into the nitride layer. Thus, repulsive effect between the charges can be reduced when the data program is executed, so that the retention characteristics and reliability of the data can be improved.

It will be apparent to those skilled in the art that various modifications and variations can be made in the present invention. Thus, it is intended that the present invention covers the modifications and variations of this invention provided they come within the scope of the appended claims and their equivalents.

What is claimed is:

1. A semiconductor device comprising:
a first insulating layer pattern on a semiconductor substrate;
a second insulating layer pattern including fluorine on the first insulating layer pattern;
a third insulating layer pattern on the second insulating layer pattern; and
a polysilicon pattern on the third insulating layer pattern.

2. The semiconductor device of claim 1, wherein the first and third insulating layer patterns are silicon oxide layer patterns, and the second insulating layer pattern is a silicon nitride layer pattern.

3. The semiconductor device of claim 1, wherein the first, second, and third insulating layer patterns each have a thickness of about 5 to 100 Å.

4. A method of manufacturing a semiconductor device, the method comprising:
forming a first insulating layer on a semiconductor substrate;
forming a second insulating layer comprising fluorine on the first insulating layer;
forming a third insulating layer on the second insulating layer;
forming a polysilicon layer on the third insulating layer; and
forming a gate pattern by patterning the polysilicon layer, the third insulating layer, the second insulating layer, and the first insulating layer.

5. The method of claim 4, wherein the forming of the second insulating layer comprising the fluorine comprises:
forming the second insulating layer on the first insulating layer by using gas containing fluorine.

6. The method of claim 5, wherein forming the second insulating layer using the gas containing fluorine comprises using SiF₄ gas and NH₃ gas to form a silicon nitride layer.

7. The method of claim 6, wherein the silicon nitride layer is formed by supplying the SiF₄ gas at a flow rate of 1 to 1500 sccm while mixing the SiF₄ gas with the NH₃ gas at a ratio of (1˜3):(4˜10).

8. The method of claim 4, wherein the forming of the second insulating layer comprising the fluorine comprises:
forming a material for the second insulating layer on the first insulating layer; and
implanting fluorine into the material for the second insulating layer through an ion implantation process.

9. The method of claim 8, wherein the implanting of the fluorine into the material for the second insulating layer comprises implanting F+ ions into the second insulating layer at a dose of 1×10¹¹˜5×10¹³ cm⁻².

10. The method of claim 4, wherein the forming of the second insulating layer comprising the fluorine comprises:
forming a material for the second insulating layer on the first insulating layer; and
implanting fluorine into the material for the second insulating layer through a plasma process.

11. The method of claim 10, wherein the implanting of the fluorine into the material for the second insulating layer comprises supplying C₄F₈ gas at a flow rate of 10˜20 sccm under power of 1000˜1500 W.

12. The method of claim 4, wherein the first and third insulating layers are silicon oxide layers.
